(19) United States
(12) Patent Application Publication
(10) Pub. No.: US 2008/0310106 A1
(43) Pub. Date: Dec. 18, 2008

(54) MULTI COMPARTMENT GREEN SHELTER

(75) Inventor: Atul Sabharwal, Washington, DC (US)

Correspondence Address: SUGHRUE MION, PLLC, 2100 PENNSYLVANIA AVENUE, N.W., SUITE 800, WASHINGTON, DC, 20037, US

(73) Assignee: MKU CYPRUS LTD, Nicosia (CY)

(21) Appl. No.: 12/125,183

(22) Filed: May 22, 2008

Related U.S. Application Data
(60) Provisional application No. 60/924,587, filed on May 22, 2007.

(51) Int. Cl. H05K 7/20; F28D 15/00; F24F 7/00

(52) U.S. Cl. 361/695; 165/104.34; 454/339

(57) ABSTRACT

A multi compartment green shelter is disclosed. The multi compartment green shelter comprises a main housing divided into a plurality of chambers. Separators are provided in the chambers to divide the chambers into compartments. At least one cooling unit is provided in middle chamber to provide cooling effect to all the compartments. Phase change material (PCM) panels are provided in the compartments to maintain preset temperature. A door is provided with each of the compartments to allow entry of a person therein.

### CROSS-REFERENCE TO RELATED APPLICATIONS

This application claims the benefit of U.S. provisional patent application Ser. No. 60/924,587, filed May 22, 2007 by the present inventors, the contents of which are incorporated herein by reference.

### FIELD OF INVENTION

This invention relates to a multi compartment green shelter. The multi compartment green shelter may, for example, be used to accommodate electrical and electronic equipments needed to operate a telecommunication system used by multiple operators for example, mobile phone services and similar other service providers.

### BACKGROUND

In the telecommunication systems plurality of electrical and electronic equipments are needed to operate the telecommunication system. The electrical and electronic equipments liberate heat due to continuous operation of the electrical and electronic equipments. Therefore, it is needed to house the electrical and electronic equipments in an air conditioned environment. The shelters may comprise a housing having an air conditioner provided therewith to maintain required temperature inside the housing. A power interface unit (PIU) may be provided in the housing to supply power to the electrical and electronic equipments housed in the shelter. The shelter may be shared by different telecom service providers to reduce overall operational may be shared by different telecom service providers to reduce overall operational cost. But, the telecom service providers do not prefer to use conventional sharable shelters due to confidentiality issues involved in their respective telecommunication system's technology. However, the telecom service providers want to reduce the operational cost to provide such telecom services.

### SUMMARY

The subject matter described herein is directed towards a multi compartment green shelter. The green shelter comprises a main housing having a plurality of partitions provided within the main housing to divide the main housing into a plurality of chambers, such as middle chamber and side chambers. Each chamber is further divided into a plurality of compartments using a plurality of separators. Each compartment is provided with a door to allow entry of a person into the compartment.

A cooling system is provided in one of the chambers, preferably the middle chamber, such for cooling to all the compartments in the main housing. One or more suction fans are provided at both sides of cooling chamber to facilitate entry of ambient air.

In one embodiment of the invention, a plurality of phase change material panels are mounted along the walls of the compartments to provide passive cooling in case of non-operation of the cooling system.

In another embodiment a power interface unit along with switched mode power supply (SMPS) and battery bank is provided in the compartments in order to provide regulated and uninterrupted power supply to electrical and electronic equipments installed in all the compartments.

These and other features, aspects, and advantages of the present subject matter will become better understood with reference to the following description and appended claims. This summary is provided to introduce a selection of concepts in a simplified form. This summary is not intended to identify key features or essential features of the claimed subject matter, nor is it intended to be used to limit the scope of the claimed subject matter.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 illustrates an embodiment of a plan view of a multi compartment green shelter.

FIG. 2 illustrates an embodiment of front view of the multi compartment green shelter.

FIG. 3 illustrates an embodiment of back view of the multi compartment green shelter.

FIG. 4 illustrates an embodiment of side view of the multi compartment green shelter.

### DETAILED DESCRIPTION

In the following detailed description, numerous specific details are described in order to provide a thorough understanding of the invention. However, the present invention may be practiced without these specific details. In other instances well known methods, procedures, components and circuits have not been described in detail so as not to obscure the present invention. Further, exemplary sizes, models, values, ranges may be given, but the present invention is not limited to these specific examples.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

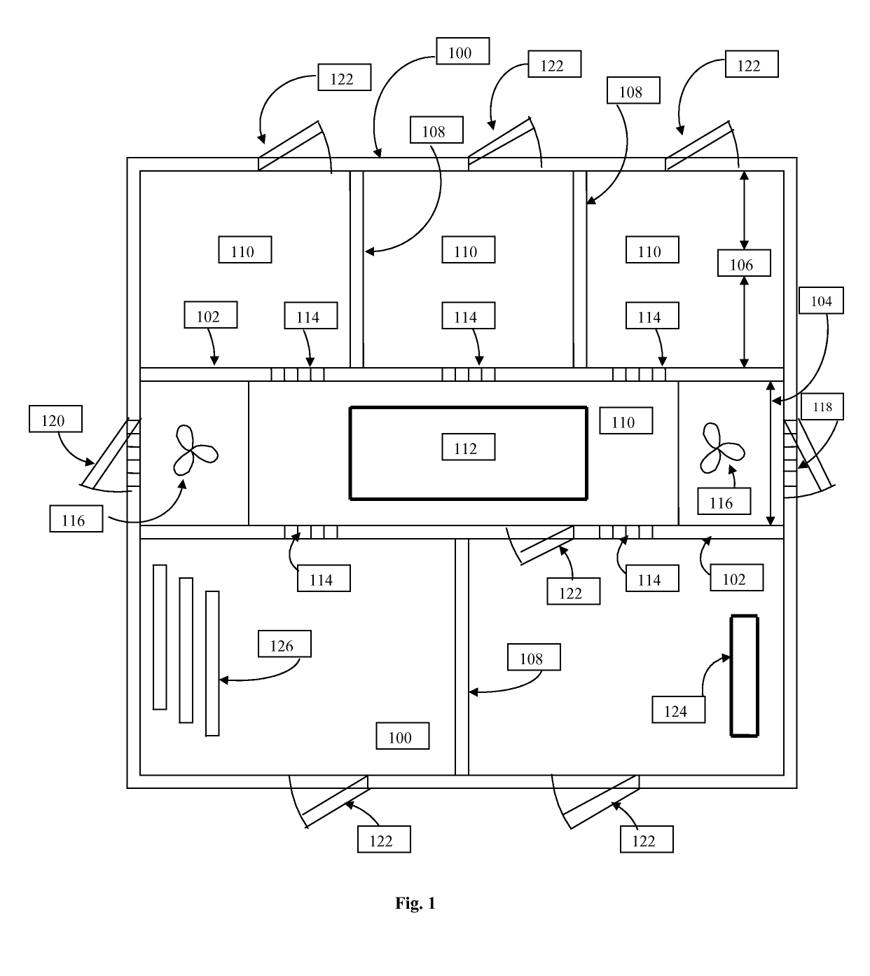

Referring to FIG. 1, an embodiment of a plan view of a multi compartment green shelter is shown. The multi compartment green shelter may comprise a main housing 100 having a plurality of partitions 102 provided in the housing 100 to divide the housing into a plurality of chambers, for example, a middle chamber 104 and side chambers 106, provided on either sides of the middle chamber 104. As depicted, a plurality of separators 108 may be provided in the side chambers 106 so as to divide said side chambers 106 into a plurality of compartments 110. The middle chamber 104 may be provided with a central cooling system, for example an air conditioner 112 such that to provide cooling effect to all the compartments 110. In one embodiment, a plurality of cooling unit may be provided in the middle chamber 104 to provide cooling effect to all the compartments 110 by allowing flow of cooled air into the chamber 104. Slots 114 may be provided near the bottom end of the partitions 102 to allow flow of cool air into the compartments 110 from the middle chamber 104. A suction fan 116 may be provided on both sides of the middle chamber 104, such that to facilitate entry of the ambient air into the cooling compartment 110 of chamber 104. Louvers 118 may be provided on both sides of the middle chamber 104 to cover opening 120 provided in the outer panel of the middle chamber 104, as and when required. In one embodiment, the compartments 110 may be used by different telecom service providers. For this purpose a door 122 may be provided with each of the compartments 110 to allow entry of a person into the respective compartment, as and when required.

In one embodiment, passive cooling means, for example, phase change material (PCM) may be provided inside each of the compartments 110 of the shelter housing 100 to maintain temperature in a range of a pre-set temperature. In one embodiment, the PCM may be filled into panels 126 made up of a heat conducting material. The amount of PCM used in the shelter housing may be decided based on the size and capacity of the housing. In one embodiment, the PCM panels may be made of high density polyethylene (HDPE) and may be mounted along with a wall of the compartments 110. The PCM panels according to an embodiment may be mounted horizontally at an angle along with the wall of the compartments 110 and having a space provided between each of the PCM panels. The PCM may be mounted such that to allow air flow through the space provided between the PCM panels.

According to an embodiment, a power interface unit (PIU) 124 may be provided in a compartment 110 to provide regulated and uninterrupted power supply to the electrical and electronic equipments provided in each of the compartment 110. According to another embodiment, separate PIU 124 may be provided in each of the compartment 110 to provide regulated and uninterrupted power supply to the electrical and electronic equipments provided in the respective compartment 110.

In one embodiment, panels used to prepare walls of a shelter may comprise an outer sheet and an inner sheet having a PUF material sandwiched between the outer and inner sheets. In one embodiment, the outer sheet may be of a heat insulting or solar heat reflecting material and the inner sheet may be of a heat conducting material. In one embodiment, the outer sheet may be made up of Fiberglass Reinforced Plastic (FRP) or Glass Reinforced Plastic (GRP). According to another embodiment, the outer sheet is made up of Zinc Aluminum Alloy coated steel painted with solar reflection compound, for example, polyvinylidene fluoride (PVDF).

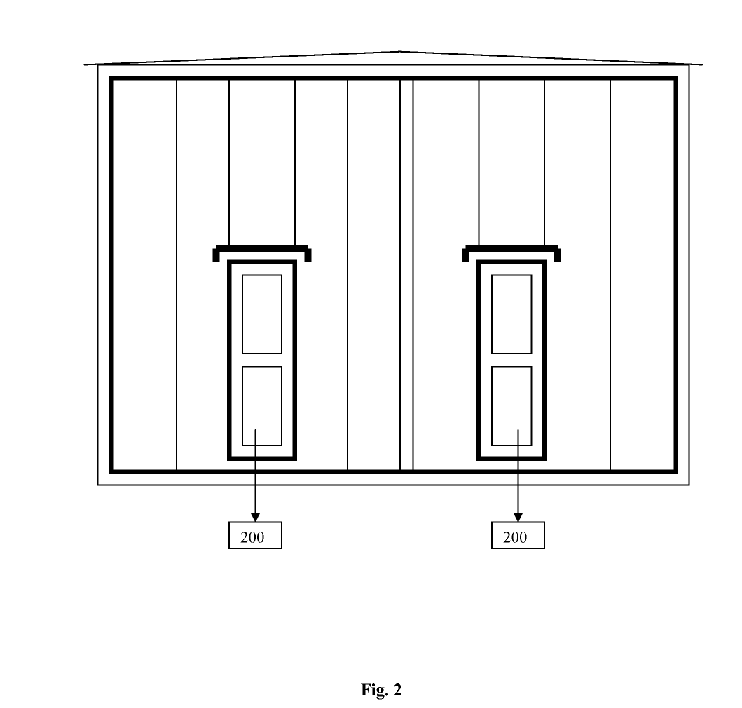

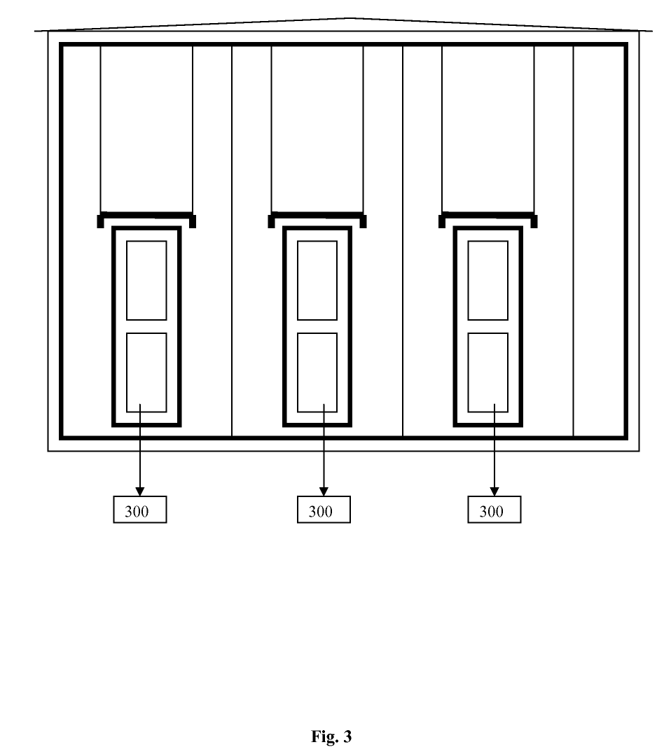

Referring to FIGS. 2 and 3, embodiments of front and back views of the multi compartment green shelter are illustrated. As depicted a plurality of doors 200 and 300 may be provided with each of the compartments 110 provided in the front and back side of the main housing 100 to allow entry of a person of the respective telecom service providers to place electrical and electronic equipments, such as base transceiver system (BTS) and other equipments in the respective compartments, needed to run the telecom services by the respective telecom service providers. Louvers 202 and 302 may be provided near the top end of each of the compartments to allow exit of the hot air from the compartment.

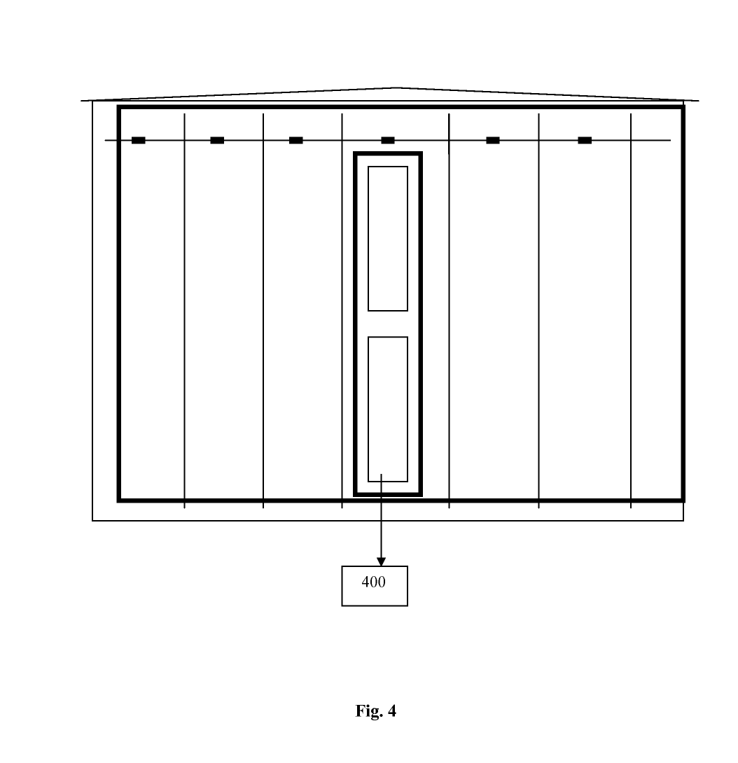

Referring to FIG. 4, an embodiment of side view of the multi compartment green shelter is illustrated. As depicted a window 400 may be provided in the left and right sides, respectively, of the middle chamber 104 of the main housing 100 to allow entry of the ambient air into cooling compartment provided in the middle chamber 104.

Certain features of the invention have been described with reference to example embodiments. However, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. A multi compartment green shelter comprising:
a main housing having a plurality of partitions provided in the main housing to divide the main housing into a plurality of chambers;
a plurality of separators provided in the chambers to divide the chambers into a plurality of compartments;
a cooling system provided in a chamber such that to provide cooling to the compartments;
a plurality of suction fan are provided at both sides of cooling chamber to facilitate entry of ambient air; and
a door is provided with each compartment to allow entry of a person into the compartment.

2. The multi compartment green shelter of claim 1, wherein the partitions are provided in the main housing to divide the main housing into a middle chamber and side chambers.

3. The multi compartment green shelter of claim 2, wherein the separators are provided in the side chambers to divide the side chambers into the plurality of compartments.

4. The multi compartment green shelter of claim 3, wherein at least one cooling system is provided in the middle chamber to provide cooling effect to all the compartments.

5. The multi compartment green shelter of claim 4, wherein at least one cooling system is provided in the compartment to provide cooling effect.

6. The multi compartment green shelter of claim 4, wherein slots are provided near bottom end of the separators to allow flow of cool air into all the compartments.

7. The multi compartment green shelter of claim 3, wherein louvers are provided near the top end of the compartments to allow exit of the hot air from the compartments.

8. The multi compartment green shelter of claim 1, further comprising a plurality of phase change material panels mounted horizontally at an angle with respect to wall of the compartments with a space provided between the PCM panels.

9. The multi compartment green shelter of claim 1, further comprising a power interface unit along with SMPS and battery bank provided in a compartment such that to provide regulated and uninterrupted power supply to electrical and electronic equipments installed in all the compartments.

10. The multi compartment green shelter of claim 9, further comprising a power interface unit along with SMPS and battery bank provided in each of the compartments to provide regulated and uninterrupted power supply to electrical and electronic equipments installed in the compartments.

11. A multi compartment green shelter comprising;
a main housing having a plurality of partitions provided in the main housing to divide the main housing into a middle and side chambers;
a plurality of separators provided in the chambers to divide the chambers into a plurality of compartments;
a cooling unit provided in the middle chamber such that to provide cooling effect to all the compartments;
a plurality of suction fans are provided at both sides of cooling chamber to facilitate entry of air;
a door is provided with the compartments to allow entry of an engineer into the compartments; and
a plurality of phase change material panels mounted along with the wall of the compartments to provide passive cooling in case of non-operation of the cooling unit.

12. The multi compartment green shelter of claim 11, wherein the separators are provided in the side chambers to divide the side chambers into the plurality of compartments.

13. The multi compartment green shelter of claim 11, wherein at least one cooling system is provided in the middle chamber to provide cooling effect to all the compartments.

14. The multi compartment green shelter of claim 13, wherein at least one cooling system is provided in the compartment to provide cooling effect.

15. The multi compartment green shelter of claim 11, wherein slots are provided near bottom end of the separators to allow flow of cool air into all the compartments.

16. The multi compartment green shelter of claim 14, wherein louvers are provided near the top end of the compartment to allow exit of the hot air from the compartments.

17. The multi compartment green shelter of claim 11, wherein the plurality of phase change material (PCM) panels are mounted horizontally at an angle with respect to the wall of the compartments with a space provided between the PCM panels.

18. The multi compartment green shelter of claim 11, further comprising a power interface unit (PIU) along with SMPS and battery bank provided in a compartment such that to provide regulated and uninterrupted power supply to electrical and electronic equipment installed in all the compartments.

19. The multi compartment green shelter of claim 11, further comprising a power interface unit (PIU) provided in each of the compartments to provide regulated and uninterrupted power supply to electrical and electronic equipment installed in the compartment.

20. A multi compartment green shelter comprising;
a main housing having a plurality of partitions provided in the main housing to divide the main housing into a plurality of chambers;
a plurality of separators provided in the chambers to divide the chambers into a plurality of compartments;
a cooling system provided in a chamber such that to provide thermal cooling to the compartments;
a plurality of suction fans are provided at both sides of cooling chamber to facilitate entry of ambient air;
a door is provided with each compartments to allow entry of a person into the compartment;
a plurality of phase change material panels mounted along with the wall of the compartments to provide passive cooling in case of non-operation of the cooling unit; and
a power interface unit along with SMPS and battery bank provided in a compartment such that to provide regulated and uninterrupted power supply to electrical and electronic equipments installed in all the compartments.

21. The multi compartment green shelter of claim 20, wherein the partitions are provided in the main housing to divide the main housing into a middle chamber and side chambers.

22. The multi compartment green shelter of claim 21, wherein the separators are provided in the side chambers to divide the side chambers into the plurality of compartments.

23. The multi compartment green shelter of claim 22, wherein at least one cooling system is provided in the middle chamber to provide cooling effect to all the compartments.

24. The multi compartment green shelter of claim 23, wherein at least one cooling system is provided in the compartment to provide cooling effect.

25. The multi compartment green shelter of claim 23, wherein slots are provided near bottom end of the separators to allow flow of cool air into all the compartments.

26. The multi compartment green shelter of claim 22, wherein louvers are provided near the top end of the compartments to allow exit of the hot air from the compartments.

27. The multi compartment green shelter of claim 20, wherein the power interface unit (PIU) along with SMPS and battery bank is provided in each of the compartments to provide regulated and uninterrupted power supply to electrical and electronic equipments installed in the compartments.
